(19) United States
(12) Patent Application Publication
(10) Pub. No.: US 2026/0258554 A1
(43) Pub. Date: Sep. 3, 2026

(54) ADJUSTABLE BAFFLE FOR COATING HOOD FOR COATING GLASS CONTAINERS

(71) Applicant: Arkema Inc., King of Prussia, PA (US)

(72) Inventor: Jeremy J. NIHART, King of Prussia, PA (US)

(21) Appl. No.: 19/474,371

(22) PCT Filed: Mar. 26, 2024
(86) PCT No.: PCT/US2024/021480

§ 371 Date: Oct. 10, 2025

Related U.S. Application Data
(60) Provisional application No. 63/458,688, filed on Apr. 12, 2023.

(51) Int. Cl. C23C 16/455; C03C 17/00

(52) U.S. Cl. CPC C23C 16/45591; C03C 17/005

(57) ABSTRACT

A coating hood or coating hood section (900) for coating articles includes a housing (902, 1104) defining an interior chamber (20b, 1104a), an inlet opening (46) through which air, gas or a vapor stream is delivered into the interior chamber (20b, 1104a), and an outlet opening (44) through which the vapor stream is exhausted from the interior chamber and delivered onto the articles. An adjustable baffle (910, 1110) is positioned within the chamber (20b) or a duct (1120) that is fluidly connected to the chamber (20b, 1104a). The adjustable baffle (910, 1110) is configured for changing, deflecting, or redirecting the flow of the vapor stream to selected, specified or predetermined area or areas of articles. The baffle (910, 1110) is movably connected in the chamber (20b) or the duct (1120) and optionally positioned substantially adjacent to the inlet opening (46) or the outlet opening

### FIELD OF THE INVENTION

This invention relates to a coating hood section for use in the process of coating glass containers. More particularly, the invention relates to an adjustable baffle that is internal to a coating hood.

### BACKGROUND OF THE INVENTION

In the process of manufacturing a glass container, the exterior surface of the glass container is typically coated with a metal (e.g., tin,)-oxide coating, for example, to improve its structural integrity.

The coating process is traditionally performed in a coating hood. Coating hoods are disclosed in U.S. Patent Application Pub. Nos. 2020/0061660; 2015/0101537; U.S. Pat. Nos. 4,389,234; 5,081,953; 5,140,940; 5,454,873; 5,599,369; 5,584,903; and PCT Patent App. Pub. Nos. WO1996020142 and WO2001025503, for example, each of which is incorporated herein by reference in its entirety. As is shown in WO2001025503, for example, in an assembly line style operation, coating vapor is sprayed onto the exterior surface of a glass container as the glass container passes through a tunnel formed in a coating hood.

Due to design and operation constraints and variations in container and bottle size, configuration, and design, oftentimes the coating process may lead to certain areas of a container or bottle having unacceptable coating thickness variations or non-uniformity over the surface, with some areas or portions on the same container or bottle having too little or too much coating. There exists a need in the industry, particularly the glass coating container and bottle industry, to provide a coating hood for coating glass containers and bottles that is capable of changing, deflecting, directing or redirecting gaseous streams comprising air and/or air comprising coating compounds or formulations to specific or predetermined locations on or areas of the glass containers or bottles during the coating process and which may be used for hot or cold end coatings of containers.

### SUMMARY OF THE INVENTION

Various aspects and embodiment of the invention may be summarized as follows:

Aspect 1: A coating hood or coating hood section (900) for coating articles, said coating hood or coating hood section comprising:
a housing (902, 1104) having a series of interconnected walls (22, 49, 39, 41, 1108) defining (i) an interior chamber (20b, 1104a), (ii) an inlet opening (46) through which air, gas or a vapor stream is delivered into the interior chamber (20b, 1104a), and (iii) an outlet opening (44) through which the vapor stream is exhausted from the interior chamber and delivered onto the articles; and
an adjustable baffle (910, 1110) positioned within the chamber (20b) or a duct (1120) that is fluidly connected to the chamber (20b, 1104a), the adjustable baffle (910, 1110) being configured for directing, changing, deflecting, or redirecting the flow of said air, gas or vapor stream to selected, specified or predetermined area or areas of articles;

said baffle (910, 1110) movably connected in said chamber (20b) or said duct (1120) and optionally positioned substantially adjacent to said inlet opening (46) or said outlet opening (44).

Aspect 2: The coating hood or coating hood section of aspect 1, wherein the baffle (910, 1110) is rotatably mounted between a lowered state and a raised state, wherein, in the lowered state, the baffle (910, 1110) is positioned to distribute said air, gas or vapor stream across a height dimension (923) which may be equal to or less a height dimension (922) of the outlet opening (44), and in the raised state, the baffle (910, 1110) is positioned to distribute said air, gas or vapor stream substantially across a height dimension (923) which is less than a height dimension (922) of the outlet opening (44), wherein said vapor stream comprises a chemical compound or formulation.

Aspect 3: The coating hood or coating hood section of aspect 2, wherein in the raised state, the baffle (910, 1110) is positioned to distribute air across only a portion of the height dimension (922) of the outlet opening (44).

Aspect 4: The coating hood or coating hood section of any one of the foregoing aspects, wherein the baffle (910, 1110) is rotatably mounted to the housing (902, 1104) or the duct (1120) about an axis of rotation (920, 1135).

Aspect 5: The coating hood or coating hood section of aspect 4, wherein the axis of rotation (920, 1135) is oriented substantially horizontally.

Aspect 6: The coating hood or coating hood section of aspect 4 or aspect 5, wherein the axis of rotation (920, 1135) extends substantially parallel to a movement direction of the articles.

Aspect 7: The coating hood or coating hood section of any one of aspects 4-6, wherein the axis of rotation (920, 1135) extends substantially perpendicular to a direction of air flow through the outlet opening (44).

Aspect 8: The coating hood or coating hood section of any one of aspects 4-7, wherein the axis of rotation (920, 1135) extends substantially perpendicular to a height dimension (922) of the outlet opening (44).

Aspect 9: The coating hood or coating hood section of any one of the foregoing aspects, further comprising means (914) for moving the baffle (910, 1110) between a lowered state and a raised state.

Aspect 10: The coating hood or coating hood section of any one of the foregoing aspects, further comprising means (921) for releasably locking the baffle (910, 1110) in either the lowered state or the raised state.

Aspect 11: The coating hood or coating hood section of aspect 9, wherein the means for moving (914) is positioned within the interior chamber (20b).

Aspect 12: The coating hood or coating hood section of any one of the foregoing aspects, wherein the baffle (910) is moveable between a lowered state and a raised state, wherein the baffle (910) is mounted to the housing (902) at a location adjacent a bottom-most wall (41) of the interconnected walls, and wherein, in the lowered state of the baffle (910), the baffle rests against the bottom-most wall (41).

Aspect 13: The coating hood or coating hood section of aspect 12, in the raised state of the baffle (910), an angle, an acute angle, an obtuse angle, or a right angle, is formed between a top side of the bottom-most wall (41), and a bottom side of the baffle (910).

Aspect 14: The coating hood or coating hood section of any one of the foregoing aspects, further comprising a plurality of dividers (38) forming blowing slots that are removably positioned within the interior chamber (20b, 1104a).

Aspect 15: The coating hood or coating hood section of aspect 14, wherein the baffle (910) is mounted to the housing (902) at a location that is downstream of the dividers (38) and upstream of the outlet opening (44).

Aspect 16: The coating hood or coating hood section of any one of the foregoing aspects, further comprising a blower (24) mounted to either the housing (902, 1104) or the duct (1120) to deliver air from the inlet (46) towards the outlet (44).

Aspect 17: The coating hood or coating hood section of any one of the foregoing aspects, further comprising means (50) for connecting the coating hood section (900) to another coating hood section, said means (50) for connecting being defined on at least one of the interconnected walls of the housing (902).

Aspect 18: The coating hood or coating hood section of any one of the foregoing aspects, wherein the baffle (910, 1110) has a shape that is substantially rectangular, substantially square, substantially circular, substantially angular, or is substantially identical to a shape of the duct (1120) or the chamber (20b) in which the baffle is located, or the inlet opening (46), or the outlet opening (44).

Aspect 19: A coating hood comprising the coating hood section of any one of the foregoing aspects, a blower (24) that is configured to deliver air from the inlet (46) towards the outlet opening (44), and an injector (420) for distributing a liquid coating chemical into the air that passes from the inlet (46) towards the outlet (44).

Aspect 20: The coating hood or coating hood section of any one of aspects 1-14 and 16-19, wherein the adjustable baffle (1110) is positioned within a duct (1120) that is fluidly connected to the chamber (1104a), and wherein the duct (1120) is connected to the inlet opening (46) of the housing (1104).

### BRIEF DESCRIPTION OF THE DRAWING FIGURES

The invention is best understood from the following detailed description when read in connection with the accompanying drawing. Included in the drawing are the following figures:

FIGS. 1, 2 and 3 show a partially schematic view of a double-vapor-loop coating hood for bottles according to the prior art.

FIG. 4 depicts a method of operating the double vapor loop coating hood of FIGS. 1-3 according to the prior art.

FIGS. 5 and 6 depict isometric views of a modular single vapor loop coating hood including two modular coating hood sections according to one embodiment of the instant invention.

FIG. 7 depicts a top plan view of the modular coating hood of FIG. 5.

FIG. 8 depicts a rear view of the modular coating hood of FIG. 5.

FIG. 9 depicts an isometric view of a sub-section of the modular coating hood section of FIG. 7, and according to another embodiment of the instant invention, wherein a baffle of the sub-section is shown in a lowered state.

FIG. 10 depicts an isometric view of the modular coating hood sub-section of FIG. 9, wherein the baffle is shown in a raised state.

FIG. 11 depicts view of a coating hood and according to yet another embodiment of the instant invention.

FIG. 12 depicts a side view of the coating hood of FIG. 11.
FIG. 13 depicts an isometric view of one coating hood section of the coating hood of FIG. 11, wherein the rear wall of the coating hood section is shown rotated to an open position.
FIG. 14 depicts an isometric view of an adapter that is mounted to the rear wall of the coating hood section of FIG. 13.
FIG. 15 depicts an isometric view of a baffle of the adapter of FIG. 14.

### DETAILED DESCRIPTION OF THE DRAWING FIGURES

The invention is best understood from the following detailed description when read in connection with the accompanying drawing figures, which shows exemplary embodiments of the invention selected for illustrative purposes. The invention will be illustrated with reference to the figures. Such figures are intended to be illustrative rather than limiting and are included herewith to facilitate the explanation of the present invention.

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both removable or rigid attachments or relationships, unless expressly described otherwise.

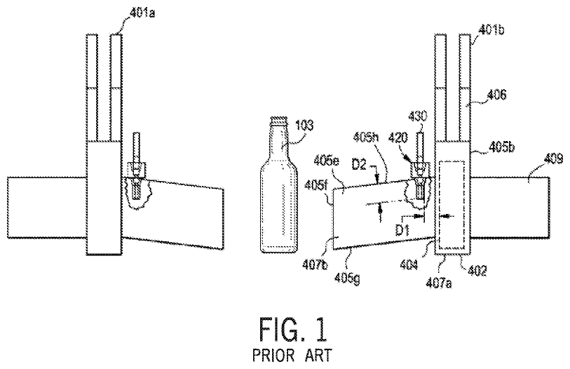

FIGS. 1-3 show a partially schematic view of a double-vapor-loop coating hood 400 for bottles according to U.S. Pat. No. 4,389,234, the entirety of which is incorporated by reference herein. The coating hood 400 generally includes two opposing hood sections 401a and 401b that are substantially identical. Although not shown, a central hood portion is positioned between the opposing hood sections 401a and 401b. Further details of the central hood portion can be found in U.S. Pat. No. 4,668,268, which is incorporated by reference in its entirety for all purposes. The bottles 103 pass through an enclosed space or tunnel that is defined between the opposing hood sections 401a and 401b. The enclosed space limits the escapement of the coating compound into the atmosphere.

The features of the hood section 401b will be described hereinafter, however, it should be understood that the hood sections 401a and 401b are substantially identical. Thus, the foregoing description of the hood section 401b also applies to hood section 401a. The hood section 401b includes a plenum housing 402. The plenum housing 402 includes a rectangular shaped base portion 407a and a manifold portion 407b that extends from the front end of the base portion 407a.

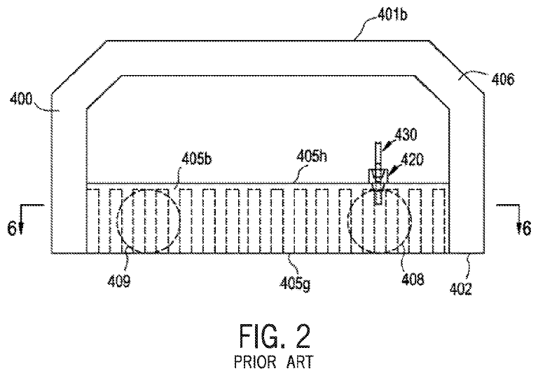

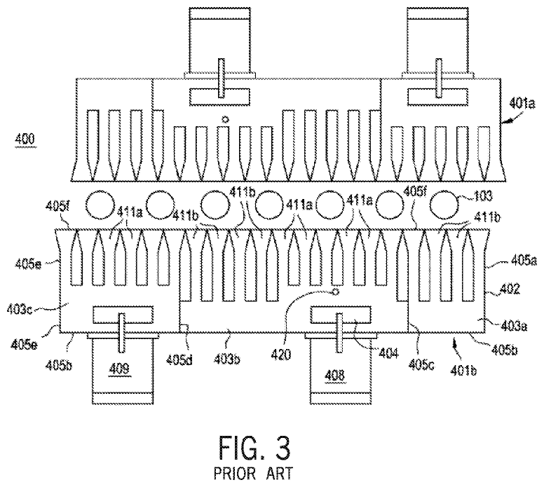

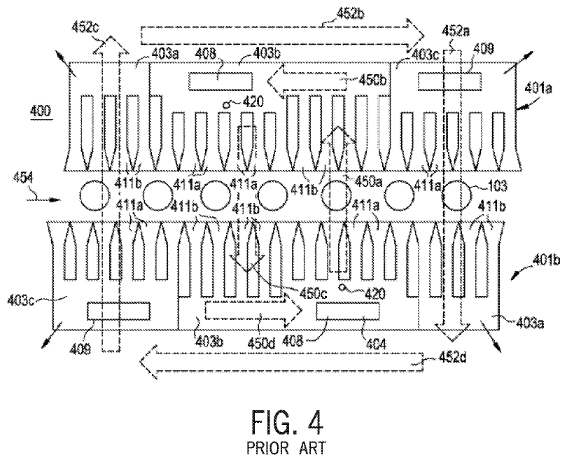

As shown in FIGS. 2 and 3, three substantially enclosed interior chambers 403a-403c are defined in the plenum housing 402. The interior chamber 403a of the housing 402 is defined by the following walls of the housing 402: top wall 405h, bottom wall 405g, front wall 405f, outer wall 405a, rear wall 405b, and interior wall 405c. The interior chamber 403b of the housing 402 is defined by the following walls of the housing 402: top wall 405h, bottom wall 405g, front wall 405f, interior wall 405c, interior wall 405d, and rear wall 405b. Lastly, the interior chamber 403c of the housing 402 is defined by the following walls of the housing 402: top wall 405h, bottom wall 405g, front wall 405f, outer wall 405e, rear wall 405b, and interior wall 405d.

Referring to FIGS. 2 and 3, the interior chambers 403a and 403c are in fluid communication by virtue of a C-shaped hollow passage 406. Thus, fluid vapors travel from interior chamber 403a to chamber 403c via hollow passage 406.

Referring now to FIG. 3, a series of openings or slots 411a and 411b are defined on the front wall 405f of the plenum housing 402. Slots 411a are configured as blowing slots, whereas slots 411b are configured as suction slots. The blowing slots 411a may be referred to herein as an outlet or outlets, and the suction slots 411b may be referred to herein as an inlet or inlets.

Two blowers 408 and 409 are mounted to the housing 402. Each blower 408 and 409 has a rotating fan blade 404 that is attached to a motor by a shaft. The fan blade 404 of the blower 408 is positioned in interior chamber 403b, and the fan blade 404 of the blower 408 is positioned in interior chamber 403c. The motors of the blowers 408 and 409 are optionally positioned outside of the housing 402.

As shown in FIG. 1, an injector 420 is mounted to the top wall 405h of the housing 402 adjacent to the fan blade 404 of the blower 408. The proximal end of the injector 420 is fluidly connected to a conduit 430 (a portion of which is shown) through which liquid coating chemical is distributed from a liquid coating supply (not shown). In FIG. 1, the side wall 405e of the housing 402 is partially cut-away to reveal the distal end of the injector 420.

The distal end of the injector 420 of the hood section 401b is positioned downstream of the blower fan blade 404, and is spaced axially by a distance ‘D1’ from the blower fan blade 404. The distal end of the injector 420 extends into the interior of the manifold portion 407b of the housing 402 by a distance ‘D2.’

Referring to FIG. 4, according to one method of operating the double vapor loop coating hood 400, the blowers 408 and 409 of each hood section 401a and 401b are first activated. The coating chemical is then delivered into the chamber 403b of each hood section 401a and 401b via the injectors 420. Thereafter the bottles 103 are conveyed along a path between the hood sections 401a and 401b, as indicated by arrow 454.

As noted above, the coating hood 400 has a double vapor loop. The primary loop 450 is depicted by air streams 450a-450d, whereas, the recycle loop 452 is depicted by air streams 452a-452d.

In the primary loop 450, the pressure side of the blowers 408 in the hood sections 401a and 401b propel air streams 450c and 450a past the injectors 420 of the hood sections 401a and 401b, respectively. Upon mixing with the coating chemical that is distributed by the injectors 420, the air streams 450c and 450a become entrained with vaporized coating chemical. The coating entrained air streams 450c and 450a are propelled out of the blowing slots 441a that are associated with the interior chambers 403b of the hood sections 401a and 401b, respectively, by the pressure side of the blowers 408. The coating entrained streams 450c and 450a pass over the bottles 103 that are positioned in front of those blowing slots 441a that are associated with the interior chambers 403c of the hood sections 401a and 401b, respectively, thereby coating the bottles 103 with the vaporized coating chemical.

The vacuum side of the blowers 408 of the hood sections 401a and 401b draws the air streams 450a and 450c through the suction slots 441b and into the interior chambers 403b of the hood sections 401a and 401b, respectively. The vacuum side of the blowers 408 of the hood sections 401a and 401b draws the coating entrained air streams 450b and 450d through the interior chambers 403 of the hood sections 401a and 401b, respectively. The primary loop then repeats as the pressure side of the blowers 408 propels the air streams 450c and 450a past the injectors 420 of the hood sections 401a and 401b, respectively.

As described above, the coating entrained air streams 450a and 450c contact the bottles 103. As the coating entrained air streams 450a and 450c contact the bottles 103, a portion of the coating entrained air streams 450a and 450c scatters outward toward the outer periphery of the hood sections. That scattered portion of the coating entrained air streams 450a and 450c is captured in the recycle loop 452.

In the recycle loop 452, the pressure side of the blowers 409 in the hood sections 401a and 401b propel air streams 452a and 452c out of the blowing slots 441a that are associated with the interior chambers 403c of the hood sections 401a and 401b, respectively. The air streams 452a and 452c mix with the scattered portion of the coating entrained air streams 450a and 450c of the primary loop 450. The coating entrained streams 452a and 452c of the recycle loop 452 pass over the bottles 103 that are positioned in front of those blowing slots 441a that are associated with the interior chambers 403c of the hood sections 401a and 401b, respectively, thereby twice coating the bottles 103 with the vaporized coating chemical.

As noted previously, the interior chambers 403a and 403c of each hood section are fluidly connected by passage 406. Thus, it follows that the vacuum side of the blowers 409 that are positioned in the interior chambers 403c of the hood sections 401b and 401a draw the coating entrained air streams 452a and 452c through the suction slots 441b that are associated with the interior chambers 403a of the hood sections 401b and 401a, respectively. The vacuum side of the blowers 409 then draw the air streams 452d and 452b through the passage 406 and into the interior chambers 403c of the hood sections 401b and 401a, respectively. The recycle loop then repeats as the pressure side of the blowers 409 in the hood sections 401a and 401b propel air streams 452a and 452c out of the blowing slots 441a that are associated with the interior chambers 403c of the hood sections 401a and 401b, respectively.

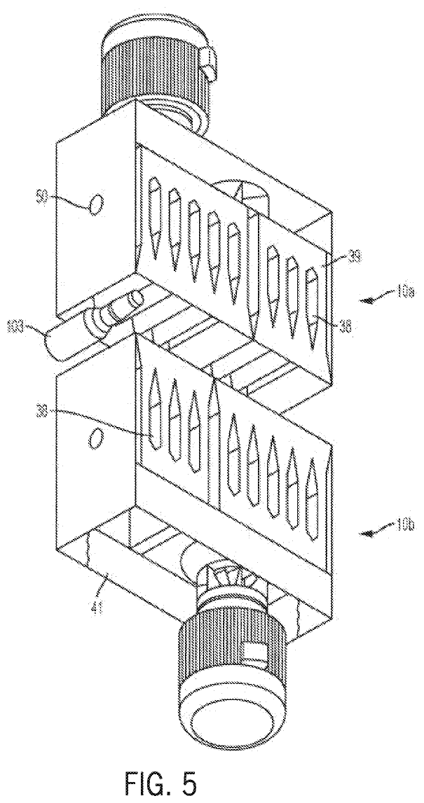

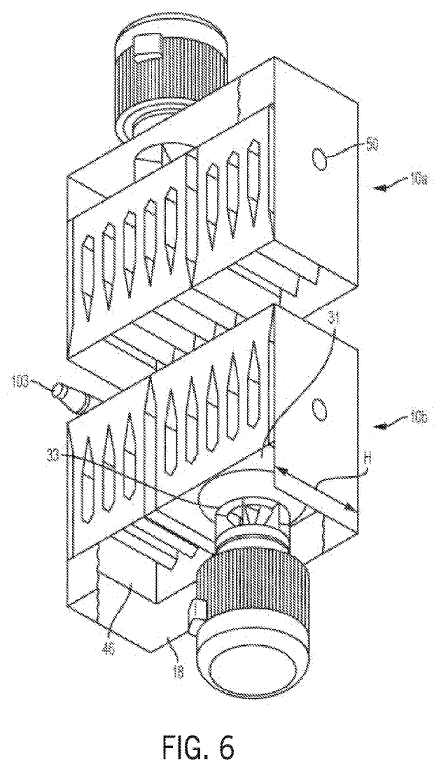

FIGS. 5-8 depict a coating hood 10 for glass articles, such as bottles. It is noted that various manifold walls are shown cut-away in FIGS. 5 and 6. It is further noted that these figures and the following description provide embodiment(s) which may be preferred. These embodiment(s) are non-limiting examples, however, and the invention includes configurations and elements which may vary from those shown and described, including for example in size, shape, number, and arrangement of the various elements described and depicted herein.

The coating hood 10 generally includes at least two or more opposing hood sections 10a and 10b. Preferably, the hood sections 10a and 10b are identical or substantially identical.

Although not shown, a central hood portion is positioned between the opposing hood sections 10a and 10b. Further details of the central hood portion can be found in, for example, U.S. Pat. No. 4,668,268, which is incorporated by reference in its entirety for all purposes. The bottles 103 pass through an enclosed space that is defined between the opposing hood sections 10a and 10b. The enclosed space limits the escapement of the coating compound into the atmosphere.

The features of the hood section 10a will be described hereinafter, however, it should be understood that preferably the hood sections 10a and 10b are identical or substantially identical. Thus, the foregoing description of the hood section 10a also applies to hood section 10b.

The hood section 10a includes a plenum housing 12, and a single blower 24 that is mounted to the plenum housing 12. The plenum housing 12 includes, for example, a substantially rectangular-shaped base portion 14 and a manifold portion 16 that extends from the front end of the base portion 14. The base portion 14 and the manifold portion 16 are interconnected by welds, for example. The plenum housing 12 may be formed from steel or aluminum sheet metal panels, for example.

A single substantially rectangular-shaped interior transfer chamber 18 is defined in the base portion 14. The fan blade blades 26 of the blower 24 are positioned within the interior chamber 18. The blower 24 operates in the reverse direction as that shown in FIG. 4, however, it should be understood that the blower 24 may be operated in the same direction as that shown in FIG. 4.

Two chambers 20a and 20b are defined in the manifold portion 16 and are physically separated by divider 22. The suction chamber 20a of the manifold portion 16 is partially enclosed by the walls of the housing 12 including divider 22. The suction chamber 20a extends between an inlet end 32 and an outlet end 30. The outlet end 30 may be a funnel-shaped opening provided in a wall 31 of the housing 12 that separates the suction chamber 20a and the transfer chamber 18. The outlet end 30 includes an opening 33 (see FIG. 6) that substantially registers with the fan blade blades 26 of the blower 24. A series of two to twelve, four to ten, preferably five to eight, more preferably six, blower slots 36 are provided in the suction chamber 20a. The suction slots 36 may be formed between adjacent structures of the housing 12 in the form of the dividers 38, the divider 22 and the housing wall 40.

Although not shown, an injector (like injector 420) may be mounted to the hood section 10a for distributing a chemical into the suction chamber 20a. The chemical may be distributed through the injector in a liquid state, which is later vaporized as it travels through the coating hood. Alternatively, the chemical may be distributed through the injector in a gaseous or vapor state.

The blowing chamber 20b of the manifold portion 16 is partially enclosed by the walls of the housing 12 including divider 22. The blowing chamber 20b extends between an inlet end 46 and an outlet end 44. As best seen in FIG. 6, the inlet end 46 of the blowing chamber 20b opens into and is in fluid communication with the interior transfer chamber 18 of the base portion 14. A series of two to twelve, four to ten, preferably five to eight, and more preferably six, blowing slots 48 are provided in the blowing chamber 20b. The blowing slots 48 are formed between adjacent structures in the form of the dividers 38, the divider 22 and the housing wall 49.

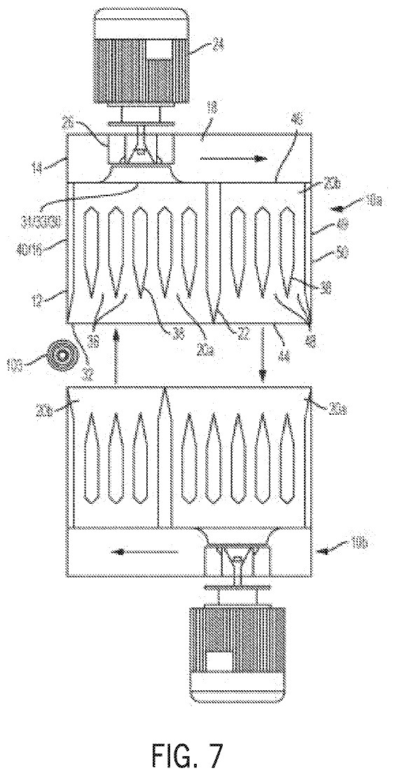

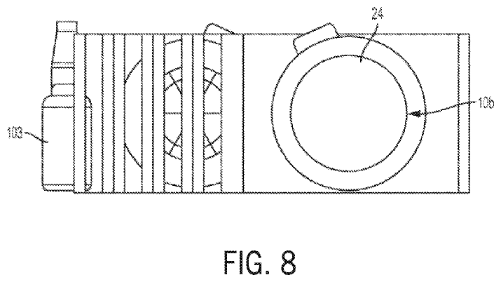

Each divider 38 of the chambers 10a and 10b may be any shape in cross-section including, for example, substantially hull-shaped in cross section (as seen in FIG. 7), and extends along the height dimension ‘H’ (see FIG. 6) of the housing 12. As shown in FIG. 5, each divider 38 is connected to the top wall 39 and the bottom wall 41 of the housing 12. While the dividers 38 may be hollow, as shown, it should be understood that air is prevented from entering the interior of the dividers 38. The dividers 38 may be removably connected to the housing 12. It should also be understood that the size, shape and number of dividers 38 and corresponding suction slots 36 may vary from that which is shown and described and are contemplated to be within the scope of the invention.

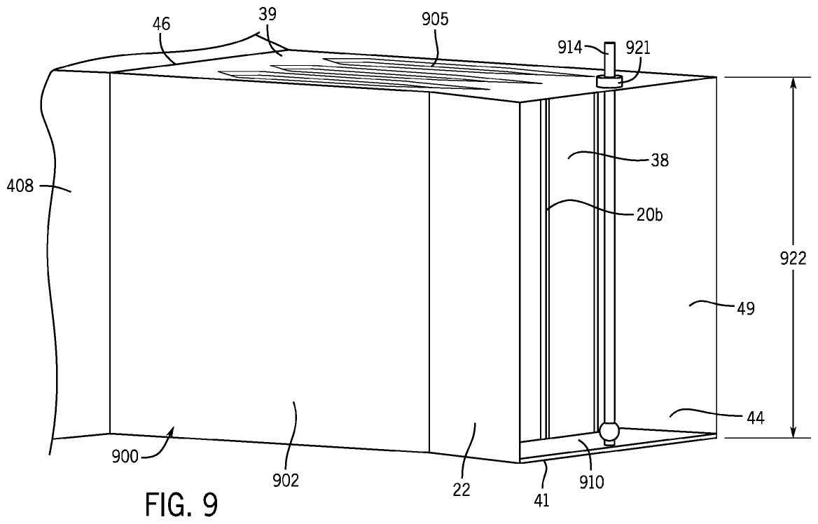

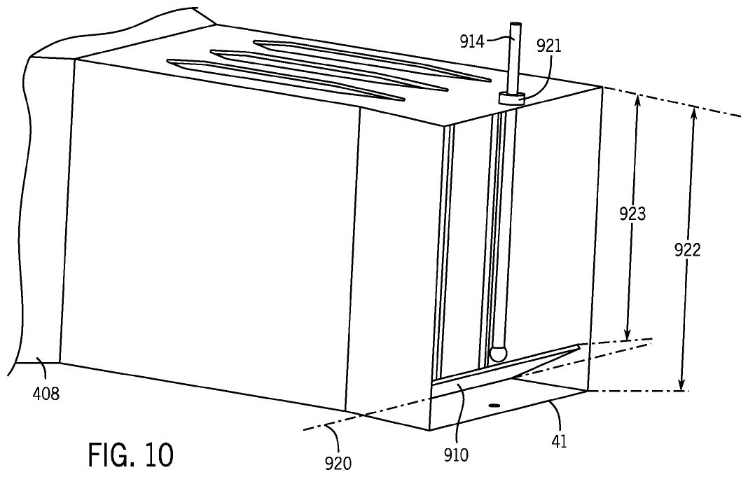

Each hood section 10a/10b includes means 50 for connecting to an adjacent hood section. Connected hood sections 10a/10b are shown in FIGS. 9 and 10. Means 50 is shown schematically in FIGS. 5 and 6. By way of non-limiting example, means 50 may be a connector, a slot, a tang, a tab, a bolt, an opening, a fastener, a screw, a raised surface, a clamp, a clip, a magnet, a protrusion, and/or any other fastening means that is/are known to those skilled in the art. Means 50 preferably provides a releasable and/or removeable connection between connected hood sections 10a/10b such that the hood sections may be connected or disconnected/disassembled as desired. However, means 50 could also provide a permanent connection, if so desired by an end user.

Means 50 is provided on the opposing side walls 40 and 49 of each hood section 10a/10b. Alternatively, means 50 may also be provided on top wall 39 and/or the bottom wall 41 of each hood section 10a/10b. One or more means 50 may be provided on each wall 39, 40, 41 and/or 49 for securing the connected hood sections 10a/10b. Means 50 may be provided on the corner(s) of a particular wall 39, 40, 41 and/or 49.

By virtue of the modular hood sections 10a/10b described herein, the coating hood manufacturer can produce substantially identical or identical hood modules that can be later attached together or removed by the customer to create a necessary hood length for a particular application. Following installation, hood sections 10a/10b can be removed from an existing installation to allow for different production speeds, or for replacement, repair or cleaning of a single hood section 10a/10b, as needed. Any number of modular hood sections 10a/10b may be connected together from two or more, at any time and as needed. Alternatively, a non-modular hood section (not shown) may be connected to one of the modular hood sections 10a/10b.

Although not shown, each modular hood section 10a/10b may include a handle or inset for lifting.

Operation of the coating hood 10 will now be described for the embodiment described above. The flow of fluid (e.g., air and/or gas) through the coating hood 10 is depicted by the arrows in FIG. 7. In operation, as shown by the arrows in FIG. 7, rotation of the fan blade of the blower 24 of the hood section 10a causes fluid to be delivered into the suction chamber 20a of the hood section 10a via inlet end 32 and then through the suction slots 36. Fluid is also delivered into the suction chamber 20a of the hood section 10a by virtue of the blowing action of the blower 24 of the hood section 10b. Referring still to the hood section 10a, the fluid is then distributed into the interior transfer chamber 18 via inlet end 30. The fluid is then delivered past the fan blades, into the blowing chamber 20b of the hood section 10a via the inlet end 46 and then through the blowing slots 48. The fluid is then distributed out of the blowing chamber 20b via the outlet end 44 and onto the bottle 103.

At the same time, rotation of the fan blade of the blower 24 of the hood section 10b causes fluid to be delivered into the suction chamber 20a of the hood section 10b via inlet end 32 and then through the suction slots 36. Fluid is also delivered into the suction chamber 20a of the hood section 10b by virtue of the blowing action of the blower 24 of the hood section 10a (as discussed above). The fluid is then distributed into the interior transfer chamber 18 of the hood section 10b via inlet end 30 of the hood section 10b. The fluid is then delivered past the fan blades, into the blowing chamber 20b of the hood section 10a via the inlet end 46 and then through the blowing slots 48. The fluid is then distributed out of the blowing chamber 20b via the outlet end 44 and onto the bottle 103.

The coating hood sections 10a/10b may be arranged to provide a single primary loop, as shown in FIG. 7, or, the hood sections 10a/10b may be connected to one or more hood sections 10a/10b to create various other loop configuration embodiment, as shown in U.S. Patent Application Pub. No. US2020/0061660, which is incorporated by reference herein in its entirety. Turning now to FIGS. 9 and 10, those figures depict an isometric view of a sub-section 900 of the modular coating hood section 10a of FIG. 7. The sub-section 900 forms part of the modular coating hood section 10a. At the outset, it should be understood that all of the above-described details relating to hood section 10a apply to the sub-section 900 of hood 10a shown in FIGS. 9 and 10.

The sub-section 900 generally includes a housing 902 constituting the housing side wall 49, divider side wall 22, top wall 39, and bottom wall 41. The walls together define interior chamber 20b. Housing 902 defines the inlet end 46 and outlet end 44 between which air is passed, as was described above. A series of openings 905 are disposed in the top wall 39, whereby each opening 905 registers with one of the dividers 38, as is also shown in FIG. 5. The interior dividers 38 are positioned within the hollow interior chamber 20b of housing 902. The dividers 38 provide blowing slots, as was discussed above.

The sub-section 900 of hood 10a includes one or more movable baffles 910. The baffle 910 is shown in a lowered state in FIG. 9 and in a raised state in FIG. 10. The baffle 910 is selectively positionable to direct an air and/or gas stream entrained with or comprising vaporized chemical compounds or formulations, onto selected specified or predetermined areas of the bottles passing substantially adjacent, substantially near or substantially next to outlet end 44. For example, in the lowered position of baffle 910 shown in FIG. 9, the air stream may be substantially uniformly distributed along the height dimension 923 (FIG. 10) which may be equal to or less than the overall height dimension 922 of the outlet opening 44 as well as along the height dimension of the bottles 103 (FIG. 7). In the raised position of baffle 910 shown in FIG. 10, the air stream may be substantially non-uniformly distributed along the height dimension 923, which may be equal to or less than the overall height dimension 922, of the outlet end 44 as well as the height dimension of the bottles 910. Specifically, in the raised position, the baffle 910 may change, direct, redirect, the air stream closer toward a certain location or areas of the bottles 103, including for example, one or more sides, the top, the neck, the finish (where cap goes on), the shoulder(s), the heel, and/or the top end of the bottles 103. And, in the raised position, the baffle 910 may either limit, substantially prevent, or prevent altogether the air stream from contacting certain locations or areas of the bottle including, for example, one or more sides, the bottom, and/or the lower end of the bottles 103.

In the lowered position of baffle 910, the baffle 910 may lie against the bottom wall 41. In the raised position of baffle 910, an angle, preferably an acute angle, may be formed between the top side of wall 41 and the lower side of baffle 910, as shown in FIG. 10. The angle may be an acute angle, an obtuse angle, or a right angle, for example.

In one embodiment, the baffle 910 is a rectangular plate having a quadrilateral shape that compliments the quadrilateral (i.e., flared) cross-sectional shape of the chamber 20b at the outlet end 44 of the housing. The shape of the baffle 910, however, may vary and may be substantially rectangular, square, circular, angular or any other shape. The baffle 910 may be composed of any material that is capable of withstanding coating processing conditions, including but not limited to any a metal or plastic material, such as, for example, stainless steel or polypropylene. The baffle 910 may be removably mounted to the housing 902 for cleaning purposes, for example.

The baffle 910 may be rotatably mounted to the sidewalls of the housing 902 about axis 920. The axis 920 is a horizontal axis that extends substantially parallel to a movement direction of the bottles 130. Axis 920 is also substantially perpendicular to the direction of air flow through the outlet end 44. Axis 920 is also substantially perpendicular to a height dimension of the bottles 103 as well as the height dimension 922 of the outlet end 44 as well as the height dimension of the tunnel through which bottles 103 pass.

The baffle 910 may be rotatably mounted about axis 920 by pins (not shown), for example. Alternatively, two projecting segments of baffle 910 may extend through holes in those housing sidewalls, and the baffle 910 may be pivotable about those projecting segments. Movement of baffle 910 may be controlled by a rod 914. One end of rod 914 is mounted to baffle 910 whereas the other end of rod 914 passes through an opening formed in the top wall 39 of housing 902. Translation of rod 914 causes rotation of baffle 910 about axis 920. The rod 914 is also positioned within the interior of housing 902. The rod 914 may be secured in any desired position by a fastener, bolt, screw, pin, magnet, or any other means 921 known to secure a rod in a desired position.

The means or mechanism for rotating baffle 910 can vary. For example, the baffle 910 can be rotated using a rod (as shown), lever, fastener, bolt, screw, nut, wheel, knob, motor, solenoid, magnet, pin, latch, or any other mechanism for causing rotation or movement that is known to those skilled in the art. It is further noted that the mechanism for rotating baffle 910 does not have to be positioned within the interior chamber 20b of housing 902. Those skilled in the art will recognize that it may be more preferable to position the mechanism on the outside of the housing 902 (e.g., on the exterior facing side of wall 49) to avoid disrupting the flow of air through outlet end 44.

The mechanism for rotating baffle 910 may be manually operated. Alternatively, rotation of baffle 910 may be controlled electronically by a motor that is connected to a computer controller. The baffle may be rotated in a continuous or non-continuous or automated fashion.

The baffle 910 is mounted within the interior chamber 20b of housing 902 at a location that is adjacent bottom wall 41 and downstream of blower 24 (FIG. 7) and dividers 38. However, the location of baffle 910 may vary to achieve a desired flow stream at the bottles 103. For example, the baffle 910 could be positioned at a location that is either at or near top wall 39, or at a location between top wall 39 and bottom wall 41. Such a positional change would affect the areas of the bottles that are sprayed with coating.

Alternatively, baffle 910 could be mounted outside of the housing 902, such as a location that is either upstream of inlet end 46 or downstream of outlet end 44. As another alternative, baffle 910 could be mounted within the interior of the housing 902 at a location that is directly upstream of the dividers 38 (e.g., mounted to or near rear wall 31).

Although only the left-hand section of hood section 10a (as viewed in FIG. 7) includes a baffle 910, it should be understood that the right-hand section of hood section 10a may also include a baffle 910. And, hood section 10b may include one or more baffles 910.

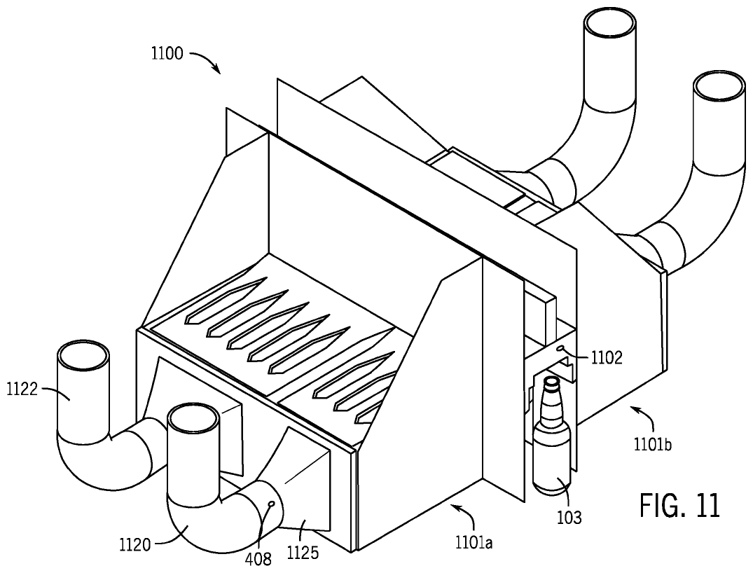

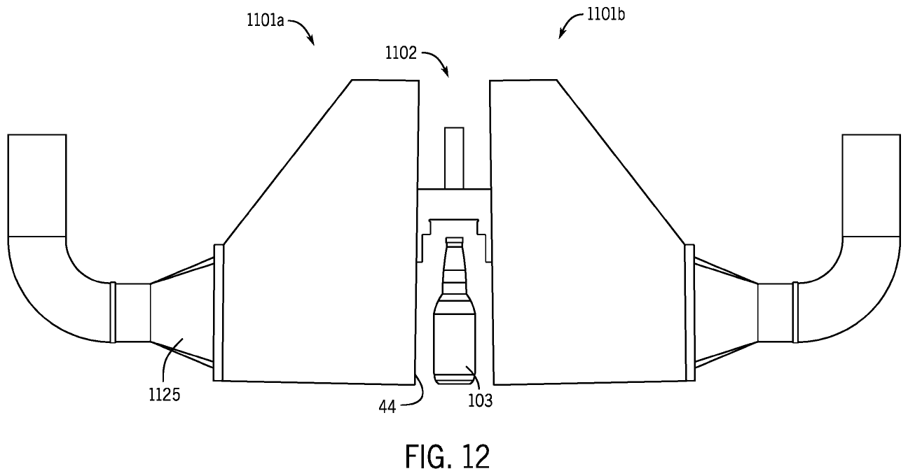

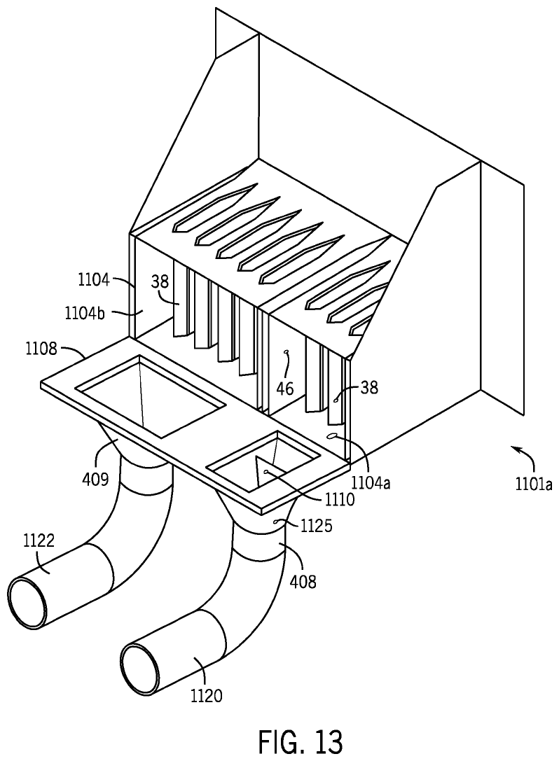

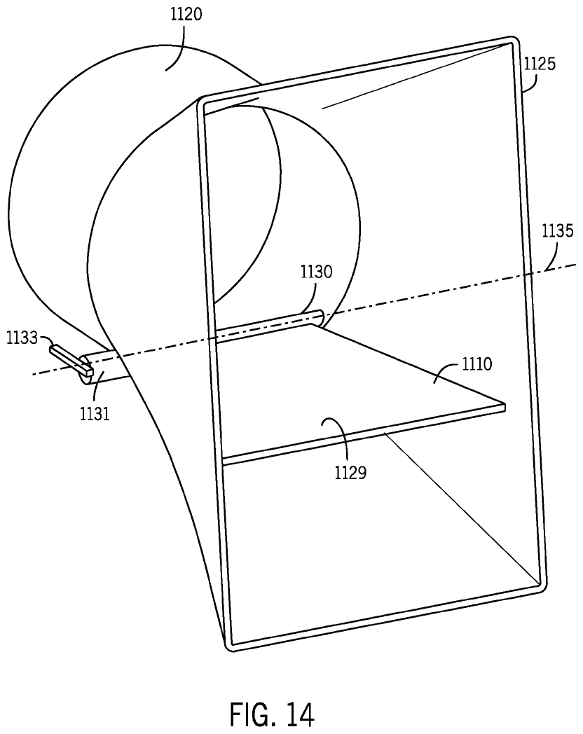

Turning now to FIGS. 11-13, those figures depict another embodiment of a coating hood 1100. The hood 1100 may constitute a single vapor loop or a double vapor loop like the hood of FIGS. 1-4. Thus, the details of hood 10a shown in FIGS. 1-4 apply to the hood 1100. The hood 1100 may also have a modular design, as shown and described herein.

The coating hood 1100 generally includes two opposing hood sections 1101a and 1101b that are substantially identical. Air, gas or a vapor stream (i.e., a moving stream of air combined with vaporized chemical compound or chemical formulation) passes through each section 1101a, 1101b and onto the bottles 103 that travel in the space between the sections. A central hood portion 1102 is positioned between the opposing hood sections 1101a and 1101b. Further details in connection with the basic structure and operation of the coating hood 1100 are provided hereinabove with respect to FIGS. 1-4 as well as in the patents that are incorporated by reference herein.

The features of the hood section 1101a will be described hereinafter, however, it should be understood that the hood sections 1101a and 1101b are substantially identical. Thus, the foregoing description of the hood section 1101a also applies to hood section 1101b.

The hood section 1101b includes a plenum housing 1104. Two substantially enclosed interior chambers 1104a and 1104b are defined in the plenum housing 1104. A series of dividers 38 are either removably or fixedly mounted within each chamber 1104a and 1104b, for the reasons described above.

Housing 1104 includes a movable (e.g., pivotable) rear wall 1108. As best shown in FIG. 13, rear wall 1108 may be pivoted downwardly or outward (or otherwise moved or removed) to access the interior of housing 1104 for cleaning or servicing, for example. One duct 1120 is mounted to rear wall 1108 for distributing air, vapor stream, and/or gas either into or from the chamber 1104a. The enlarged end 1125 of duct 1120 that connects to rear wall 1108 may be referred to as an adapter 1125. The adapter 1125 may be considered as forming part of housing 1104 and/or duct 1120. The duct 1120 may also be considered as forming part of housing 1104. The blower 408 may be mounted to duct 1120. The location of blower 408 can vary. For example, the blower 408 may be positioned within chamber 1104a of housing 1104.

A second duct 1122 is mounted to rear wall 1108 for distributing air and/or gas either from or into the chamber 1104b. The blower 409 may be mounted to duct 1122. The location of blower 409 can vary. For example, the blower 409 may be positioned within chamber 1104b of housing 1104.

An injector (like injector 420) may be mounted to the top wall of the housing 1104, or another location such as in the duct 1120, for the reasons described above. The injector may be either upstream or downstream of the baffle 1110.

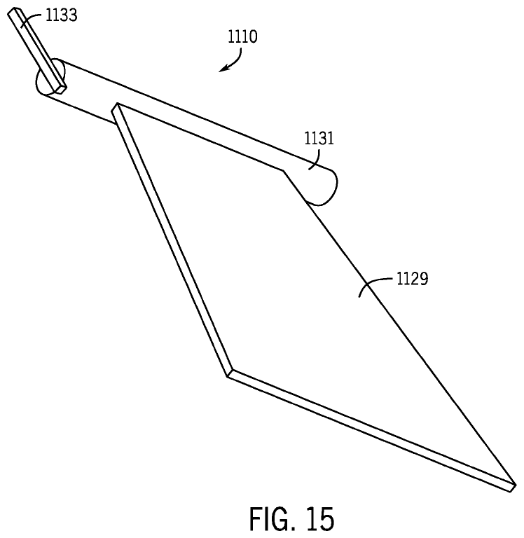

As best shown in FIGS. 14 and 15, the baffle 1110 is rotatably (or otherwise movably) mounted within the interior of adapter 1125. Like baffle 910, baffle 1110 is also positioned to distribute an air, gas or vapor stream, which may comprise a chemical compound or formulation, such as a metal oxide, across a height dimension which may be equal to or less a height dimension of the outlet opening (44) of the housing 1104.

Baffle 1110 includes a trapezoidal shaped panel 1129 having a size and shape that substantially matches the interior shape of the adapter 1125 in which the panel 1129 is movably positioned. In some embodiments, the size and shape of panel 1129 may vary. The panel 1129 extends from a cylindrical hub 1131 of the baffle 1110. The hub 1131 is positioned within openings 1130 formed in the sidewall of adapter 1125. At least a portion of hub 1131 is positioned within the interior of adapter 1125.

A handle 1133 is mounted to the end of hub 1131. The handle 1133 is positioned outside of adapter 1125 and duct 1120. Handle 1133 may be used to manually pivot the entire baffle 1110 about axis 1135. Axis 1135 is oriented substantially horizontally, substantially parallel to a movement direction of the articles 103, and/or substantially perpendicular to a direction of air flow through the outlet opening (44). Like baffle 910, movement of baffle 1110 may be manual (using handle 1133) or automated using a motor and/or controller. The motor may be positioned either within or outside of duct 1120.

The baffle may be made of any material able to withstand the harsh coating processes including metal such as carbon or rolled steel, or high temperature plastics and rubber. The baffle may be sealed at its connection point to prevent leakage of chemistry/vapors.

The coating hoods described herein may be used for coating glass bottles, glass articles, hollow glass articles, metallic articles (e.g., aluminum bottles or cans), or any other article known to those skilled in the art with a chemical compound or chemical formulation such as metal oxides.

The coating hoods described herein provide coating hoods for coating glass containers and bottles that are capable of changing, deflecting, directing or redirecting gaseous/vapor/air streams comprising coatings (e.g., chemical compounds or formulations) to specific or predetermined locations on or areas of the glass containers or bottles during the coating process and which may be used for hot or cold end coatings of containers and bottles. The environment inside a coating hood is severe and harsh. The coating hoods described herein enable coating-containing vapors, streams, air to be directed to specific, predetermined locations on the containers or bottles while the hood in in operation and requires no internal opening or operator exposure to vapors while making such changes during the glass coating process. Without use of the invention described herein, much or even most of the coating may end up on the bottom of the hood. The coating hoods described herein result in better and more efficient use of coating materials, less waste, and thus less emissions to exit streams which is better for the environment. It also provides a safer process for the operator. Particularly when used with a modular embodiment, it also enables servicing of a portion of the hood (for example a single module as opposed to the whole side of the hood) for cleaning and removing broken glass.

Within this specification embodiments have been described in a way which enables a clear and concise specification to be written, but it is intended and will be appreciated that embodiments may be variously combined or separated without parting from the invention. For example, it will be appreciated that all preferred features described herein are applicable to all aspect of the invention described herein.

Numerous variations, changes and substitutions will occur to those skilled in the art without departing from the spirit of the invention. For example, the baffle 910 and 1110 may be translated vertically between the raised and lowered positions, like a garage door. Also, although only one baffle 1110 is shown in adapter 1125, it should be understood that hood section 1101a may include multiple baffles. Accordingly, it is intended that the appended aspects cover all such variations as fall within the spirit and scope of the invention.

1. A coating hood or coating hood section for coating articles, said coating hood or coating hood section comprising:
a housing having a series of interconnected walls defining (i) an interior chamber, (ii) an inlet opening through which air, gas or a vapor stream is delivered into the interior chamber, and (iii) an outlet opening through which the vapor stream is exhausted from the interior chamber and delivered onto the articles; and
an adjustable baffle positioned within the chamber or a duct that is fluidly connected to the chamber, the adjustable baffle being configured for directing, changing, deflecting, or redirecting the flow of said air, gas or vapor stream to selected, specified or predetermined area or areas of articles;
said baffle movably connected in said chamber or said duct and optionally positioned substantially adjacent to said inlet opening or said outlet opening.

2. The coating hood or coating hood section of claim 1, wherein the baffle is rotatably mounted between a lowered state and a raised state, wherein, in the lowered state, the baffle is positioned to distribute said air, gas or vapor stream across a height dimension which may be equal to or less a height dimension of the outlet opening, and in the raised state, the baffle is positioned to distribute said air, gas or vapor stream substantially across a height dimension which is less than a height dimension of the outlet opening, wherein said vapor stream comprises a chemical compound or formulation.

3. The coating hood or coating hood section of claim 2, wherein in the raised state, the baffle is positioned to distribute air across only a portion of the height dimension of the outlet opening.

4. The coating hood or coating hood section of claim 1, wherein the baffle is rotatably mounted to the housing or the duct about an axis of rotation.

5. The coating hood or coating hood section of claim 4, wherein the axis of rotation is oriented substantially horizontally.

6. The coating hood or coating hood section of claim 4, wherein the axis of rotation extends substantially parallel to a movement direction of the articles.

7. The coating hood or coating hood section of claim 4, wherein the axis of rotation extends substantially perpendicular to a direction of air flow through the outlet opening.

8. The coating hood or coating hood section of claim 4, wherein the axis of rotation extends substantially perpendicular to a height dimension of the outlet opening

9. The coating hood or coating hood section of claim 1, further comprising means for moving the baffle between a lowered state and a raised state.

10. The coating hood or coating hood section of claim 1, further comprising means for releasably locking the baffle in either the lowered state or the raised state.

11. The coating hood or coating hood section of claim 9, wherein the means for moving is positioned within the interior chamber.

12. The coating hood or coating hood section of claim 1, wherein the baffle is moveable between a lowered state and a raised state, wherein the baffle is mounted to the housing at a location adjacent a bottom-most wall of the interconnected walls, and wherein, in the lowered state of the baffle, the baffle rests against the bottom-most wall.

13. The coating hood or coating hood section of claim 12, in the raised state of the baffle, an angle, an acute angle, an obtuse angle, or a right angle, is formed between a top side of the bottom-most wall, and a bottom side of the baffle.

14. The coating hood or coating hood section of claim 1, further comprising a plurality of dividers forming blowing slots that are removably positioned within the interior chamber.

15. The coating hood or coating hood section of claim 14, wherein the baffle is mounted to the housing at a location that is downstream of the dividers and upstream of the outlet opening.

16. The coating hood or coating hood section of claim 1, further comprising a blower mounted to either the housing or the duct to deliver air from the inlet towards the outlet.

17. The coating hood or coating hood section of claim 1, further comprising means for connecting the coating hood section to another coating hood section, said means for connecting being defined on at least one of the interconnected walls of the housing.

18. The coating hood or coating hood section of claim 1, wherein the baffle has a shape that is substantially rectangular, substantially square, substantially circular, substantially angular, or is substantially identical to a shape of the duct or the chamber in which the baffle is located, or the inlet opening, or the outlet opening.

19. A coating hood comprising the coating hood section of claim 1, a blower that is configured to deliver air from the inlet towards the outlet opening, and an injector for distributing a liquid coating chemical into the air that passes from the inlet towards the outlet.

20. The coating hood or coating hood section of claim 1, wherein the adjustable baffle is positioned within a duct that is fluidly connected to the chamber, and wherein the duct is connected to the inlet opening of the housing.
